(19) United States
(12) Patent Application Publication
(10) Pub. No.: US 2005/0056870 A1
(43) Pub. Date: Mar. 17, 2005

(54) Stress sensitive microchip with premolded-type package

(76) Inventors: Maurice S. Karpman, Brookline, MA (US); Nicole Hablutzel, Cambridge, MA (US); Peter W. Farrell, Lunenburg, MA (US); Michael W. Judy, Wakefield, MA (US); Lawrence E. Felton, Hopkinton, MA (US)

Correspondence Address: Steven G. Saunders;Bromberg & Sunstein LLP, 125 Summer Street, Boston, MA, 02110-1618, US

(21) Appl. No.: 10/952,330

(22) Filed: Sep. 28, 2004

Related U.S. Application Data
(63) Continuation-in-part of application No. 10/326,640, filed on Dec. 19, 2002.

(51) Int. Cl. H01L 23/48

(52) U.S. Cl. 257/222

(57) ABSTRACT

A packaged microchip has a microchip attach region with a lower modulus of elasticity than other portions of the package base. Specifically, the packaged microchip includes a stress sensitive microchip, and a package having a base with a primary region and an attach region. A surface of the microchip is coupled to the attach region of the package. The attach region has a modulus of elasticity that is less than the modulus of elasticity of the primary region.

### PRIORITY

This patent application is a continuation-in-part of and claims priority from U.S. patent application Ser. No. 10/326,640, filed Dec. 19, 2002, entitled, “PACKAGED MICROCHIP WITH ISOLATOR HAVING SELECTED MODULUS OF ELASTICITY,” and naming Maurice Karpman as inventor, the disclosure of which is incorporated herein, in its entirety, by reference.

### RELATED APPLICATION

This patent application also is related to U.S. patent application Ser. No. ______, filed on even date herewith, entitled, “PACKAGED MICROCHIP WITH PREMOLDED-TYPE PACKAGE,” and naming Maurice S. Karpman, Nicole Hablutzel, Peter W. Farrell, Michael W. Judy, Lewis Long, and Lawrence E. Felton as inventors, the disclosure of which is incorporated herein, in its entirety, by reference.

### FIELD OF THE INVENTION

The invention generally relates microchips and, more particularly, the invention relates packaging techniques for microchips.

### BACKGROUND OF THE INVENTION

Microelectromechanical systems (“MEMS”) are used in a growing number of applications. For example, MEMS currently are implemented as gyroscopes to detect pitch angles of airplanes, and as accelerometers to selectively deploy air bags in automobiles. In simplified terms, such MEMS devices typically have structure suspended above a substrate, and associated electronics that both senses movement of the suspended structure and delivers the sensed movement data to one or more external devices (e.g., an external computer). The external device processes the sensed data to calculate the property being measured (e.g., pitch angle or acceleration).

The associated electronics, substrate, and movable structure typically are formed on one or more dies (referred to herein simply as a “die”) that are secured within a package. The package includes interconnects that permit the electronics to transmit the movement data to the external devices. To secure the die to the package interior, the bottom surface of the die commonly is bonded (e.g., with an adhesive or solder) to an internal surface of the package. Accordingly, in such case, substantially all of the area of the bottom die surface is bonded to the internal surface of the package.

MEMS inertial sensors/die are sensitive to environmental factors, such as disparate material expansion between the die and its package. Specifically, this disparate expansion commonly is caused by mismatched coefficients of thermal expansion (“CTE”) between the materials forming the bottom die surface and the internal package surface that secures the die. In fact, these CTE mismatches can cause the sensor to deliver incorrect motion measurements. For example, when implemented as an accelerometer within an automobile airbag system or as a gyroscope in an automobile traction control system, CTE mismatches can produce results that can cause the automobile to operate erratically. Consequently, such incorrect measurements can lead to bodily injury or death for drivers, their passengers, or others near the moving automobile (e.g., people in other automobiles).

To reduce this problem, MEMS inertial sensors commonly are secured within ceramic packages rather than within two other well known and widely used package types; namely, “transfer molded” packages and “premolded” packages. Specifically, both transfer molded packages and premolded packages have a copper leadframe to which the die is secured. The CTE difference between copper and silicon (i.e., the material forming the die), however, is much greater than the CTE difference between ceramic and silicon. Those in the art thus are motivated to use ceramic packages for MEMS inertial sensors rather than the other two types of packages.

Undesirably, ceramic packages are relatively expensive to produce. In addition, securing a MEMS sensor die within a ceramic package requires a larger number of process steps (when compared to the other noted types of packages), thus further increasing production costs. In fact, in many MEMS sensor applications using ceramic packages, the packaging cost far exceeds the cost of producing the MEMS sensor itself.

### SUMMARY OF THE INVENTION

In accordance with one aspect of the invention, a packaged microchip has a microchip attach region with a lower modulus of elasticity than other portions of the package base. Specifically, the packaged microchip includes a stress sensitive microchip, and a package having a base with a primary region and an attach region. A surface of the microchip is coupled to the attach region of the package. In illustrative embodiments, the attach region has a modulus of elasticity that is less than the modulus of elasticity of the primary region.

In illustrative embodiments, the ratio of the attach region modulus and primary region modulus is no greater than about 0.5. Moreover, the surface of the microchip preferably does not contact the primary region. Different materials may be used for the attach region. For example, the attach region may include an elastomeric polymer, such as silicone.

The package may include a leadframe. In such case, the primary region may be secured to the leadframe, while the attach region is secured to the primary region. In addition, the package may be a premolded-type package. Among other things, the microchip may be either an accelerometer or a gyroscope. To further minimize stress, the surface of the microchip is considered to be coupled to the attach region of the package at a contact area. This contact area, however, may be less than the total surface area of the surface of the microchip.

In accordance with another aspect of the invention, a premolded-type package has a leadframe, a first material molded to the leadframe, a wall forming a cavity having a base, and a second material. The first material is molded about at least a portion of the second material so that the second material forms at least a part of the base of the cavity. The first material has one of a different modulus of elasticity or coefficient of thermal expansion than at least one of those of the second material.

Both the first and second materials may be moldable material (i.e., capable of being subjected to molding processes, such as injection molding processes). In illustrative embodiments, the first material has a modulus that is greater than that of the second material. In alternative embodiments, the second material is a non-moldable material.

In accordance with other aspects of the invention, a method of forming a packaged microchip forms a premolded package by molding a first material to a leadframe, and molding the first material to a second material. The method then secures a stress sensitive microchip to the second material.

Among other ways, the method may use two-shot molding processes or insert molding processes to mold the first material to the second material. When using insert molding processes, the second material may have a coefficient of thermal expansion that is substantially equal to the coefficient of thermal expansion of the microchip. In some embodiments, the second material has a modulus of elasticity that is less than the modulus of elasticity of the first material. For example, the ratio of the modulus of elasticity of the second material to the modulus of elasticity of the first material is no greater than about 0.5. In illustrative embodiments, the first material includes a liquid crystal polymer and the second material includes an elastomeric polymer.

The premolded package may be formed by molding the first material to the leadframe to form a longitudinal space, and then coupling a film to the periphery of the space to occlude the space. The film supports the second material. Finally, after the second material substantially adheres to the first material, the film may be removed.

### BRIEF DESCRIPTION OF THE DRAWINGS

The foregoing and advantages of the invention will be appreciated more fully from the following further description thereof with reference to the accompanying drawings wherein:

FIG. 1 schematically shows a partially cut-away view of a packaged microchip that may be produced in accordance with illustrative embodiments of the invention.

FIG. 2A schematically shows a cross-sectional view of a first embodiment of the packaged microchip shown in FIG. 1 along line A-A.

FIG. 2B schematically shows a cross-sectional view of a second embodiment of the packaged microchip shown in FIG. 1 along line A-A

FIG. 2C schematically shows a cross-sectional view of a third embodiment of the packaged microchip shown in FIG. 1 along line A-A.

FIG. 3 shows a process of producing the packaged microchip shown in FIG. 1 using two-shot molding processes.

FIG. 4 shows a process of producing the packaged microchip shown in FIG. 1 using insert molding processes.

### DESCRIPTION OF ILLUSTRATIVE EMBODIMENTS

Illustrative embodiments of the invention substantially reduce chip stresses associated with conventional premolded-type packages so they can be successfully used to package stress sensitive microchips. Accordingly, because of the lower cost of premolded packages when compared to ceramic packages, such embodiments can significantly reduce production costs while maintaining desired performance. Details of illustrative embodiments are discussed below.

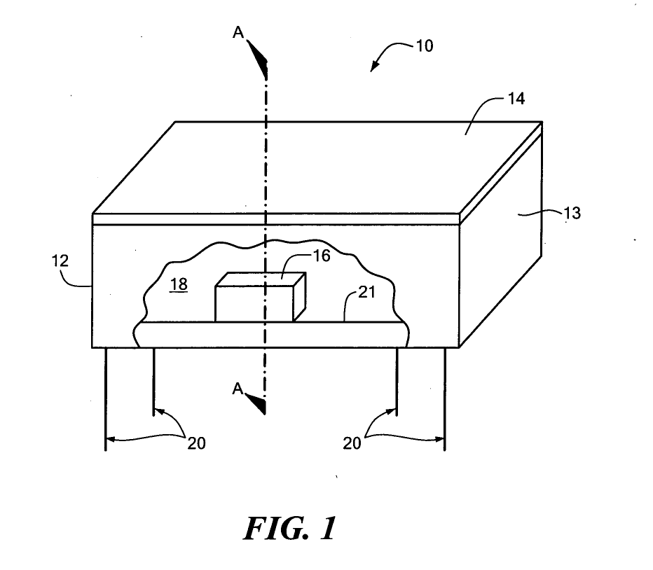

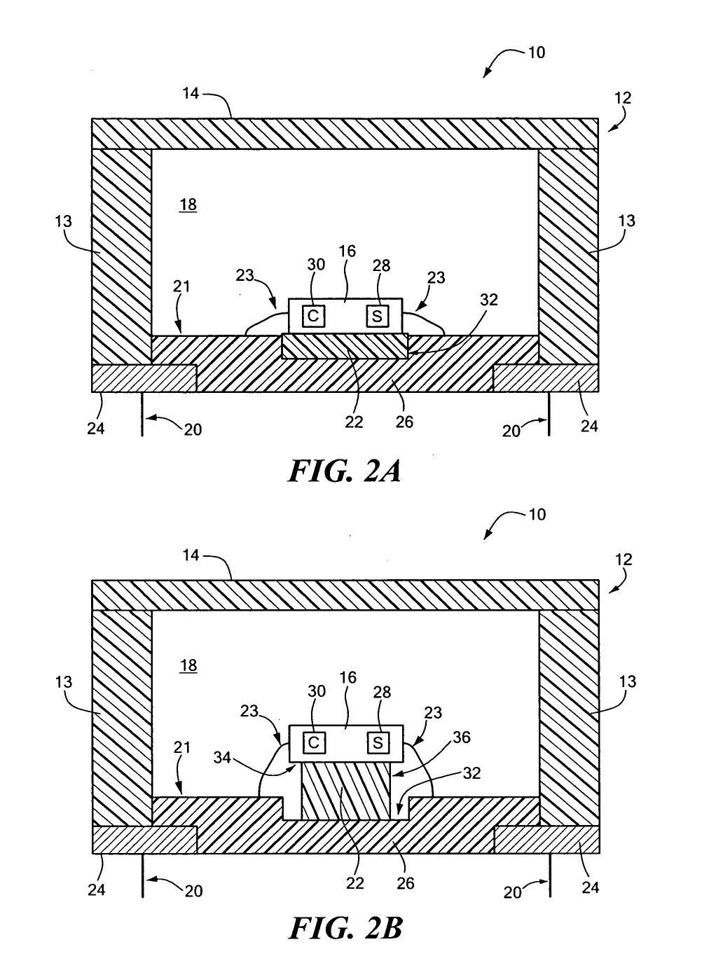

FIG. 1 schematically shows a partially cut-away isometric view of a packaged microchip 10 that can implement various embodiments of the invention. In illustrative embodiments, the packaged microchip 10 is a MEMS device implemented as an angular rate sensor. Accordingly, for illustrative purposes, various embodiments are discussed herein as a MEMS angular rate sensor. The MEMS devices shown in FIGS. 1, 2A-2C thus may be generally identified herein as angular rate sensors 10. It should be noted, however, that discussion of various embodiments as a MEMS angular rate sensor is exemplary only and thus, not intended to limit all embodiments of the invention. Accordingly, some embodiments may apply to other types of microchip devices, such as integrated circuits. In addition, embodiments of the invention can be applied to other types of MEMS devices, such as MEMS-based optical switching devices and MEMS-based accelerometers. Moreover, some embodiments of the invention can be applied to microchip devices mounted in packages that are not hermetically sealed.

The angular rate sensor 10 shown in FIG. 1 includes a conventional premolded-type package 12 having walls 13 extending from a base 21, a lid 14 secured to the walls 13 to seal the package 12, and a conventional angular rate sensor die 16 secured within the sealed interior 18. The angular rate sensor die 16 includes the well known mechanical structure and electronics (discussed below) that measure angular rate about a given axis. A plurality of pins 20 extending from the package 12 electrically connect with the angular rate sensor die 16 to permit electrical communication between the angular rate sensor electronics and an exterior device (e.g., a computer).

The angular rate sensor die 16 is bonded to an attachment region 22 (shown in FIGS. 2A-2C and also referred to herein as second material, which also is identified by reference number 22) of the base 21 of the package interior 18. Among other ways, the die 16 may be bonded by means of an adhesive layer. In illustrative embodiments, the attachment region 22 includes a material that substantially minimizes stresses between the remainder of the package 12 and the sensor die 16. In one embodiment of the invention, the attachment region 22 is formed from a moldable material having a lower modulus of elasticity than that of the molding material making up the remainder of the package 12. For example, such a package 12 may be formed by using conventional two-shot injection molding processes, or dispensing processes. In another embodiment, the attachment region 22 is a non-moldable material (e.g., a silicon isolator) secured to molding material forming much of the remainder of the package 12. Details of these and other embodiments are discussed below.

FIGS. 2A-2C schematically show three embodiments of the packaged microchip 10 along line A-A of FIG. 1. In particular, FIG. 2A schematically shows a first embodiment in which a first moldable material 26 (hereinafter “first material 26”) substantially integrally mates with a leadframe 24 (not shown in FIG. 1) and the noted attachment region 22. To minimize stress, the noted moldable material that makes up much of the package 12 is different than the material making up the attachment region 22. Details of this relationship are discussed below.

As noted above, the die 16 includes conventional silicon MEMS structure 28 to mechanically sense angular rotation, and accompanying electronics 30. Such structure 28 and electronics 30 (both shown schematically in FIG. 2A) illustratively are formed on a silicon-on-insulator wafer, which has an oxide layer between a pair of silicon layers. Alternatively, the structure 28 and electronics 30 may be formed by conventional surface deposition techniques, or some other conventional means known in the art. As an example, among other things, the MEMS structure 28 may include one or more vibrating masses suspended above a silicon substrate 26 by a plurality of flexures. The structure 28 also may include a comb drive and sensing apparatus to both drive the vibrating masses and sense their motion.

Accordingly, the electronics 30 may include, among other things, the driving and sensing electronics that couple with the comb drive and sensing apparatus, and signal transmission circuitry. Wires 23 electrically connect the accompanying electronics 30 with the pins 20. Exemplary MEMS angular rate sensors are discussed in greater detail in U.S. Pat. Nos. 5,939,633 and 6,505,511, which are assigned to Analog Devices, Inc. of Norwood, Mass. The disclosures of both of the noted patents are incorporated herein, in their entireties, by reference.

In alternative embodiments, the MEMS structure 28 and accompanying electronics 30 are on different dies 16. For example, the die 16 having the MEMS structure 28 may be mounted to the package 12 at a first attachment region 22, while the die 16 having the accompanying electronics 30 may be mounted to the package 12 at a second attachment region 22. Alternatively, both dies 16 may be mounted to the same attachment region 22. In some cases, one of the dies 16 (e.g., a stress sensitive die 16) may be mounted to an attachment region 22 having stress reduction properties, while the other die 16 (e.g., a non-stress sensitive die 16) may be mounted directly to the package 12.

The die 16, which is a microchip and/or integrated circuit, is sensitive to both linear and torsional stress. In this context, the term “sensitive” generally means that the operation of the structure 28 and/or electronics 30 on the die 16 can be compromised when subjected to such stress. For example, as suggested above, stress applied to the die 16 can cause the flexures suspending the mass to bend or compress to some extent. As a consequence, the mass may not vibrate at a prescribed rate and angle, thus producing a quadrature problem. As a further example, the comb drive may become misaligned, or the electronics 30 may become damaged. Any of these exemplary problems undesirably can corrupt the resulting data produced by the MEMS die 16. Accordingly, for these reasons, the die 16 or other microchip may be referred to as being “stress sensitive.”

To solve these stress related problems, the attachment region 22 illustratively may be formed from a material having a CTE that more closely matches that of the die 16 than that of the molding material forming the remainder of the package 12. In other words, the CTE of the attachment region 22 contacting the die 16 may be closer to that of the die substrate 26 than that of the molding material forming much of the remainder of the package 12. To that end, the attachment region 22 may be formed from silicon, which has a CTE that matches that of a silicon substrate. Of course, other materials may be used, depending upon the substrate type.

While the CTE of the attachment region 22 is matched with the CTE of the die 16 (in this embodiment), it is not matched with the CTE of the remainder of the package 12. Accordingly, the remainder of the package 12 and attachment region 22 may expand/contract at different rates as their temperatures change. Undesirably, absent further refinement, this rate variation can cause the second order effect of transmitting some thermal stress to the die 16. Accordingly, rather than (or in addition to) matching the CTEs of the die 16 and attachment region 22, some other embodiments form the attachment region 22 from a material having a modulus of elasticity that substantially negates both the noted second order stress and CTE mismatches.

More specifically, in such embodiments, the package 12 is formed from at least two materials; namely, a first material 26 that makes up much of the package 12 (i.e., the portion referred to above as the remainder of the package 12), and a second moldable material 22 (hereinafter “second material 22”) that makes up the attachment region 22. In illustrative embodiments, the second material 22 is much softer than the first material 26. If the softness of the second material 22 is sufficiently lower than that of the first material 26, CTE mismatches should not affect die performance. To that end, the material forming the attachment region 22 contacting the die 16 (i.e., the second material 22) is selected, relative to the first material 26, to ensure that no more than a negligible thermal stress is transmitted to the die 16. In other words, the ratio of the two moduli (noted immediately below) is selected so that no more than a negligible amount of stress is transmitted from the package 12 to the die 16 (via the attachment region 22). Such negligible amount of stress should have a negligible impact on die performance.

A negligible impact on performance means that the die 16 produces a signal that is satisfactory for its intended purpose. For example, a negligible error may be considered to have occurred when the output results can be used (for their intended purpose) without the need for additional corrective circuitry to correct a stress-induced error. As known by those skilled in the art, such results depend upon the application for which the die 16 is produced. If the die 16 is a roll-over angular rate sensor, for example, a negligible error may be considered to occur if the die results are within about fifteen percent of the results it would produce in a completely unstressed condition. In other applications, however, to be a negligible error, the results must be much closer to the unstressed results.

In illustrative embodiments, the ratio of the modulus of elasticity of the second material 22 to the modulus of elasticity of the first material 26, is no greater than about 0.5. Accordingly, lower ratios also should provide satisfactory results. Such relative moduli should permit the second material 22 to attenuate stress to negligible levels regardless of CTE mismatches.

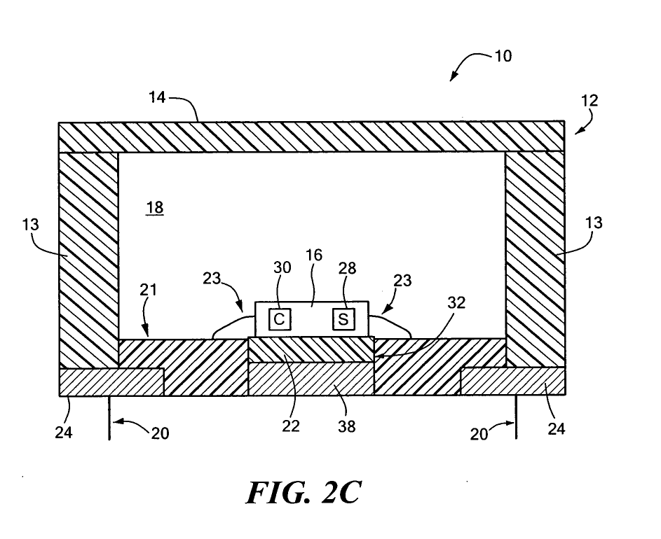

In the embodiment shown in FIG. 2A, the leadframe 24 does not have a die paddle 38 for supporting the substrate. Instead, the first and second materials 26 and 22 support the die 16. As discussed in greater detail below with regard to FIG. 3, the first material 26 is formed with a recess 32 into which the second material 22 is injected. When cured, the first and second materials 26 and 22 form a substantially continuous surface. The die 16 preferably does not contact the less soft first material 26, thus contacting the attachment region/second material only 22. In alternative embodiments, however, the second material 22 may extend completely through the base 21 to the bottom of the package 12.

FIG. 2B schematically shows another embodiment of the invention, which, in a manner similar to the embodiment of FIG. 2A, also does not use a die paddle 38. Specifically, in this embodiment, the attachment region 22 contacts only a portion of the bottom surface 34 of the die 16, thus further reducing stress. The point of contact on the die bottom surface 34 and the top surface of the attachment region 22 (i.e., contact area) thus is smaller than the total area of the die bottom surface 34. More specifically, the attachment region 22 has a top surface 28 that is bonded to the bottom surface 34 of the die 16. The attachment region top surface 28 has a surface area that is smaller than that of the bottom surface 34 of the die 16, thus forming a space 36 between a portion of the die bottom surface 34 and the package 12. Among other ways, the top surface of the attachment region 22 may be shaped to match that of the die 16, or be some other shape, such as a cross shape. Accordingly, by minimizing direct contact in this manner, a relatively large portion of the die bottom surface 34 is not subjected to direct torsional stress produced by the package 12.

Although the second material 22 in this embodiment extends above the first material 26 in the base 21, in alternative embodiments it may be flush with or be below the first material 26. In either case, the second material 22 contacts less than all of the surface area of the bottom of the die 16. Moreover, there may be a space 36 between the first and second material 22 (e.g., all the way around the second material 22, or around much of the second material 22). In either case, it is preferred that the die 16 not contact the first material 26, although it may make contact in some instances. In such instances, those skilled in the art can determine the tradeoffs associated with permitting such contact.

There may be instances, however, when the die paddle 38 could be used to support the attachment region 22. To those ends, FIG. 2C schematically shows another embodiment of the invention, in which the attachment region/second material 22 is formed over the die paddle 38. The attachment region 22 may include electrically conductive properties for, among other things, grounding the die 16 to the die paddle 38. Moreover, the attachment region 22 also may include thermally conductive properties.

In the embodiment shown in FIG. 2C, molding processes form the first material 26, which makes up much of the package 12, relative to the die paddle 38, to produce a recess 32 for receiving the second material 22. Among other ways, the second material 22 may be formed to be substantially flush with the first material 26 (e.g., similar to FIG. 2A) or form a space 36 with the first material 26 (e.g., similar to FIG. 2B) to minimize surface contact. In alternative embodiments, however, etching processes etch a recess 32 in the die paddle 38 to receive the second material 22.

FIG. 3 shows a process of forming the packaged sensor 10 shown in FIGS. 2A-2C, in which the second material 22 has a modulus of elasticity that is less than that of the first material 26. The process begins at step 300, in which conventional processes pattern and otherwise process a sheet of copper in accordance with conventional processes to form the leadframe 24. After the leadframe 24 is substantially formed, the first material 26 is added. In illustrative embodiments, the first material 26 is a plastic material that adheres well to the leadframe 24 material. For example, the first material 26 may be a liquid crystal polymer, which has a low moisture permeability. Accordingly, forming the package 12 with such a polymer should provide hermeticity.

In the embodiment that does not use a die paddle 38, the first material 26 illustratively may be formed to have a recess 32 for receiving the second material 22. Alternatively, such embodiment may be formed so that the first material 26 forms a longitudinal space (not shown) through the base of the package 12. In that case, a low tack film or other support material may be coupled to the outside of the bottom side of the package 12 to support the second material 22 when it is added (see step 304 for discussion of adding second material 22). After the second material 22 adheres to the remaining part of the package 12, the film or support material may be removed.

In the embodiment using the die paddle 38, the die paddle 38 may be etched to form the recess 32 for receiving the second material 22. Alternatively, the first material 26 may be formed to cooperate with the die paddle 38 to produce the noted recess 32. Those skilled in the art, however, can determine other means for receiving the second material 22.

The process thus continues to step 304, in which conventional processes add the second material 22 to any of the above noted configurations. As discussed above, the second material 22 illustratively is a moldable material having a lower modulus of elasticity than that of the first material 26. In addition, the first and second materials 26 and 22 illustratively are selected so that they have a sufficient bond to one another when cured. As noted above, when used with a liquid crystal polymer first material 26, the second material 22 may include an elastomeric polymer, such as silicone or rubber.

Any conventional material deposition process may be used to execute steps 302 and 304, such as two shot injection molding processes or dispensing processes. The molds further may include specialized shapes to form interlocking portions for the two materials.

After the second material 22 cures, the leadframe 24 carries an array of open packages 12 having walls 13 that form cavities. Accordingly, a die 16 may be secured to the attachment region 22 (i.e., the second material 22) in the base 21 of the cavity of each package 12 (step 306) in the array. As noted above, each die 16 may be secured by conventional means, such as with an adhesive. The portion of the second material 22 that surrounds the attachment region 22 may be considered to form a primary portion (because it forms a primary portion of the package 12). As also noted above, in illustrative embodiments, the die 16 contacts the attachment region 22 only; it does not contact the primary portion.

It then is determined at step 308 if passivation is required to ensure that no moisture can contact the die 16. If passivation is required, the process continues to step 310, in which a passivation layer, such as a gel, is applied to the exterior of the die 16. After passivation is applied, the process continues to step 312 (discussed below).

Conversely, if no passivation layer is required, the process skips step 310 and secures the lid 14 to each package 12 (step 312). In some embodiments, the packages 12 and die 16 may be inserted into a gas chamber, which saturates the interiors 18 with a buffer gas before the lid 14 is inserted. Finally, after securing the lid 14, the leadframe 24 and lid 14 may be diced (step 314) to produce a plurality of packaged microchips.

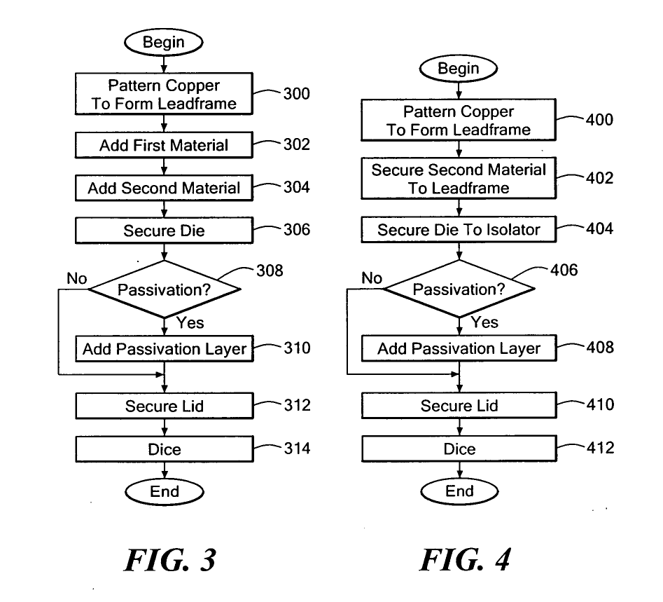

FIG. 4 shows another process in which the second material 22 is pre-formed and then secured to the package 12 by molding processes, such as insert-molding processes. The process begins at step 400, in which conventional processes pattern and otherwise process a sheet of copper in accordance with conventional processes to form the leadframe 24. In a manner similar to other embodiments, the leadframe 24 is patterned for ultimate use within a plurality of different packages.

After the leadframe 24 is substantially formed, the second material 22 is secured to the leadframe 24 (step 402). Exemplary materials for the second material 22 include one that matches the die 16 (e.g., a non-moldable material, such as silicon) or a cured elastomeric polymer. Accordingly, in illustrative embodiments, insert molding process secure the second material 22 to the leadframe 24 by injecting the first material 26 into a mold cavity having the second material 22. By forming around the second material 22, the first material 26 secures the second material 22 to the leadframe 24. In other words, the first material 26 molds to the second material 22. Of course, in the embodiment discussed above with regard to FIG. 3, the first material 26 also molds to the second material 22.

It should be noted that discussion of an insert molding process is not intended to limit the scope of all embodiments of the invention. Instead, discussion of such processes is exemplary of but one means of integrating the second material 22 to the remainder of the package 12.

The process continues in a similar manner to the process discussed with regard to FIG. 3. Specifically, after the first material 26 cures, the leadframe 24 carries an array of open packages 12. Accordingly, a die 16 may be secured to the attachment region 22 (i.e., the second material 22) within the base 21 of each package 12 (step 404) in the array. The portion of the second material 22 that surrounds the attachment region 22 is considered to form a primary portion (because it forms a primary portion of the package 12). As noted above, in illustrative embodiments, the die 16 contacts the attachment region 22 only; it does not contact the primary portion.

It then is determined at step 406 if passivation is required to ensure that no moisture can contact the die 16. If passivation is required, the process continues to step 408, in which a passivation layer, such as a gel, is applied to the exterior of the die 16. After passivation is applied, the process continues to step 410 (discussed below).

Conversely, if no passivation layer is required, the process skips step 408 and secures the lid 14 to each package 12 (step 410). In some embodiments, the packages 12 and die 16 may be inserted into a gas chamber, which saturates the interiors 18 with a buffer gas before the lid 14 is inserted. Finally, after securing the lid 14, the leadframe 24 and lid 14 may be diced (step 412) to produce a plurality of packaged microchips. In illustrative embodiments, the lid 14 is produced from the first material 26 (e.g., a liquid crystal polymer).

Accordingly, among other benefits, various embodiments discussed above enable stress sensitive microchips to be packaged in high yields while significantly reducing the stresses associated with currently available low cost packaging techniques. Stress sensitive microchips thus can receive the low cost benefits of premolded packages while avoiding higher costs and stress associated with ceramic packages.

Although the above discussion discloses various exemplary embodiments of the invention, it should be apparent that those skilled in the art can make various modifications that will achieve some of the advantages of the invention without departing from the true scope of the invention.

1. A packaged microchip comprising:
a stress sensitive microchip having a surface; and
a package having a base with a primary region and an attach region, the surface of the microchip coupled to the attach region of the package,
the attach region having an attach region modulus of elasticity, the primary region having a primary region modulus of elasticity, the attach region modulus of elasticity being less than the primary region modulus of elasticity.

2. The packaged microchip as defined by claim 1 wherein the ratio of the attach region modulus of elasticity and the primary region modulus of elasticity is no greater than about 0.5.

3. The packaged microchip as defined by claim 1 wherein the surface of the microchip does not contact the primary region.

4. The packaged microchip as defined by claim 1 wherein the attach region comprises an elastomeric polymer.

5. The packaged microchip as defined by claim 4 wherein the elastomeric polymer includes silicone.

6. The packaged microchip as defined by claim 1 wherein package includes a leadframe, the primary region being secured to the leadframe, the attach region being secured to the primary region.

7. The packaged microchip as defined by claim 1 wherein the microchip includes an accelerometer or a gyroscope.

8. The packaged microchip as defined by claim 1 wherein the package is a premolded-type package.

9. The packaged microchip as defined by claim 1 wherein the surface of the microchip is coupled to the attach region of the package at a contact area, the contact area being less than the surface area of the surface of the microchip.

10. A premolded-type package comprising:
a leadframe;
a first material molded to the leadframe;
a wall forming a cavity having a base; and
a second material,
the first material molded about at least a portion of the second material, the second material forming at least a part of the base of the cavity, the first material having one of a different modulus of elasticity or coefficient of thermal expansion than at least one of those of the second material.

11. The premolded-type package as defined by claim 10 wherein the first material is a first moldable material having a first modulus of elasticity, the second material being a second moldable material having a second modulus of elasticity,
the first modulus of elasticity being greater than the second modulus of elasticity.

12. The premolded-type package as defined by claim 10 wherein the second material is a non-moldable material.

13. A method of forming a packaged microchip, the method comprising:
forming a premolded package, forming comprising:
molding a first material to a leadframe; and
molding the first material to a second material; and
securing a stress sensitive microchip to the second material.

14. The method as defined by claim 13 further comprising using a two-shot molding process to mold the first material to the second material.

15. The method as defined by claim 13 further comprising using an insert molding process to mold the first material to the second material.

16. The method as defined by claim 15 wherein the second material has a coefficient of thermal expansion that is substantially equal to the coefficient of thermal expansion of the microchip.

17. The method as defined by claim 13 wherein the second material has a modulus of elasticity that is less than the modulus of elasticity of the first material.

18. The method as defined by claim 17 wherein the ratio of the modulus of elasticity of the second material to the modulus of elasticity of the first material is no greater than about 0.5.

19. The method as defined by claim 13 wherein forming the premolded package includes:
molding the first material to the leadframe to form a longitudinal space;
coupling a film to the periphery of the space to occlude the space, the film supporting the second material; and
removing the film after the second material substantially adheres to the first material.

20. The method as defined by claim 13 wherein the first material includes a liquid crystal polymer and the second material includes an elastomeric polymer.
